(19) United States
(12) Patent Application Publication
(10) Pub. No.: US 2021/0229393 A1
(43) Pub. Date: Jul. 29, 2021

(54) LAMINATED BODY ASSEMBLY UNIT, LAMINATED BODY, AND METHOD FOR MANUFACTURING LAMINATED BODY

(71) Applicant: ENPLAS CORPORATION, Kawaguchi-shi, Saitama (JP)

(72) Inventor: Tomohiro SAITO, Saitama (JP)

(21) Appl. No.: 16/769,133

(22) PCT Filed: Dec. 12, 2018
(86) PCT No.: PCT/JP2018/045589

§ 371 Date: Jun. 2, 2020

(30) Foreign Application Priority Data
Dec. 19, 2017 (JP) 2017-242542

(51) Int. Cl. B32B 3/30; B32B 37/16; G02B 3/00

(52) U.S. Cl. CPC B32B 3/30; G02B 3/0012; G02B 3/0037; B32B 37/16

(57) ABSTRACT

The present invention provides a laminated body assembly kit with which two substrates can be easily aligned even when, for example, facing surfaces thereof have high-density pattern portions. A laminated body assembly kit with an alignment function of the present invention includes a first substrate 10 and a second substrate 20 that are to be laminated together. The first substrate 10 has a lens portion 11 on a surface thereof opposite to a facing surface thereof that faces the second substrate 20. The second substrate 20 has an alignment mark portion 21 on at least one surface thereof. The first substrate 10 and the second substrate 20 respectively have the lens portion 11 and the alignment mark portion 21 such that, in a set laminated state, the alignment mark portion 21 of the second substrate 20 is located at a focal position of the lens portion of the first substrate 10. An image of the alignment mark portion 21 that is formed in the lens portion 11 in the set laminated state is an image indicating that the set laminated state has been achieved.

### TECHNICAL FIELD

The present invention relates to a laminated body assembly unit, a laminated body, and a method for manufacturing a laminated body.

### BACKGROUND ART

In laminated bodies in which a plurality of substrates are laminated together, there are cases where the substrates are arranged in a predetermined positional relationship to realize a function, as in a printed wiring board, an analysis chip, and the like, for example. In the case of a printed wiring board, for example, it is important that substrates are arranged in such a positional relationship that allows interconnects of the substrates laminated together to properly conduct electricity. In the case of an analysis chip, for example, the analysis chip may have a structure including a flow channel, a conductive film, and the like inside. With this structure, for example, an analysis chip can be manufactured using two substrates. This analysis chip may be formed by patterning a recess serving as a flow channel on a facing surface of one substrate and a conductive film serving as an electrode on a facing surface of the other substrate, and laminating the substrates together such that their facing surfaces face each other. In this manner, a laminated body having the flow channel and the electrode therein is obtained, and can be used as the analysis chip. When forming the above-described chip, it is important to laminate the two substrates such that the flow channel through which a specimen flows and the conductive film serving as an analytical electrode are arranged in the correct positional relationship.

Some methods for achieving a laminated state with a correct positional relationship in constructing a laminated body like the printed wiring board and the analysis chip include: for example, a method in which one of the substrates is provided with a protruding frame surrounding an outer periphery thereof, and alignment is performed by fitting the other substrate into the frame; a method in which a pin portion is provided on the facing surface of one of the substrates, while a through hole is formed in the other substrate, and alignment is performed by inserting the pin portion into the through hole; and the like (Patent Document 1 etc.). However, these methods have the problem in that it is difficult to plan a design, because an alignment frame, a pin portion, and the like need to be provided on the facing surfaces of the substrates, while, on the other hand, pattern portions, such as an interconnect and a conductive film need to be provided on the same surfaces. Moreover, since these methods involve the fitting into the frame or the insertion of the pin portion into the through hole, the two substrates need to be of a certain thickness and strength in terms of handleability. However, if, for example, one of the substrates is a bendable film or the like, the formation of the frame, the pin portion, the through hole, and the like, and the handling, are also difficult.

### CITATION LIST

### Patent Documents

Patent Document 1: JP H7-202435A

### SUMMARY OF INVENTION

### Technical Problem

To address the above-described problems, an object of the present invention is to provide a laminated body assembly kit with which two substrates can be easily aligned even when, for example, facing surfaces thereof have high-density pattern portions, a method for manufacturing a laminated body in which alignment is achieved, and a laminated body in which alignment is achieved.

### Solution to Problem

In order to accomplish the above-described object, a laminated body assembly kit with an alignment function of the present invention includes a first substrate and a second substrate that are to be laminated together,
wherein the first substrate has a lens portion on a surface thereof opposite to a facing surface thereof that faces the second substrate,
the second substrate has an alignment mark portion on at least one surface thereof,
the first substrate and the second substrate are respectively provided with the lens portion and the alignment mark portion such that, in a set laminated state, the alignment mark portion of the second substrate is located at a focal position of the lens portion of the first substrate, and
an image of the alignment mark portion that is formed in the lens portion in the set laminated state is an image indicating that the set laminated state has been achieved.

A laminated body of the present invention includes a first substrate and a second substrate,
wherein the first substrate has a lens portion on a surface thereof opposite to a facing surface thereof that faces the second substrate,
the second substrate has an alignment mark portion on at least one surface thereof,
the first substrate and the second substrate are laminated together such that the lens portion of the first substrate and the alignment mark portion of the second substrate are located opposing each other, and
an image of the alignment mark portion of the second substrate that is formed in the lens portion is an image that is formed when the alignment mark portion is located at a focal position of the lens portion.

A method for manufacturing a laminated body of the present invention uses the laminated body assembly kit with an alignment function of the present invention and includes:
placing the first substrate and the second substrate facing each other such that the lens portion and the alignment mark portion are located opposing each other,
aligning the first substrate and the second substrate with each other by adjusting an image of the alignment mark portion of the second substrate that is formed in the lens portion to an image that is formed when the alignment mark portion is located at a focal position of the lens portion, and
fixing the first substrate and the second substrate in this state.

### Advantageous Effects of Invention

With the laminated body alignment kit of the present invention, it is possible to easily align two substrates even when, for example, facing surfaces thereof have high-density pattern portions and obtain a laminated body in which the substrates are correctly aligned.

### BRIEF DESCRIPTION OF DRAWINGS

FIG. 1 schematically shows an example of the present invention: FIG. 1(A) shows plan views of a portion of the first substrate and the second substrate when viewed from above; FIG. 1(B) shows cross-sectional views of the first substrate and the second substrate; and FIG. 1(C) is a cross-sectional view showing a laminated state in which the first substrate and the second substrate are laminated together.

FIG. 2 schematically shows laminated states of the first substrate and the second substrate of an example of the present invention, as well as images of an alignment mark portion that is formed in the lens portion: in each of FIGS. 2(A) to 2(E), a cross-sectional view showing the laminated state is shown on the left side, and a plan view showing an image of the alignment mark portion that is formed in the lens is shown on the right side.

FIG. 3 schematically shows the numbers and the positions of lens portions of the first substrate and alignment mark portions of the second substrate, of an example of the present invention: in each of FIGS. 3(A), 3(B), and 3(C), a plan view of a facing surface of the second substrate is shown on the left side, a plan view of an opposite surface of the first substrate is shown on the right side, and a side view of the first substrate is shown in the middle.

FIG. 4 schematically shows the first substrate and the second substrate, of an example of the present invention, in the case where the lens portion is a cylindrical lens: in each of FIGS. 4(A) and 4(B), a plan view of the facing surface of the second substrate is shown on the left side, a plan view of the opposite surface of the first substrate is shown on the right side, and a side view of the first substrate is shown in the middle.

FIG. 5 schematically shows the first substrate and the second substrate, of an example of the present invention, in the case where the lens portion is a lens array: in each of FIGS. 5(A) and 5(B), a plan view of the facing surface of the second substrate is shown on the left side, a plan view of the opposite surface of the first substrate is shown on the right side, and a side view of the first substrate is shown in the middle.

FIG. 6 schematically shows the first substrate and the second substrate that have patterning portions, of an example of the present invention: FIG. 6(A) shows a side view of the first substrate, a plan view of a facing surface thereof, and a plan view of the opposite surface thereof in this order from the left side; FIG. 6(B) shows a side view of the second substrate and a plan view of the facing surface thereof in this order from the left side; and FIG. 6(C) shows a top view and a bottom view of a laminated body in this order from the left side.

FIG. 7 schematically shows the first substrate and the second substrate that have patterning portions, of an example of the present invention: FIG. 7(A) shows a side view of the first substrate, a plan view of the facing surface thereof, and a plan view of the opposite surface thereof in this order from the left side; FIG. 7(B) shows a side view of the second substrate and a plan view of the facing surface thereof in this order from the left side; and FIG. 7(C) shows a top view and a bottom view of a laminated body in this order from the left side.

FIG. 8 schematically shows the first substrate and the second substrate that have patterning portions, of an example of the present invention: FIG. 8(A) shows a side view of the first substrate, a plan view of the facing surface thereof, and a plan view of the opposite surface thereof in this order from the left side; FIG. 8(B) shows a side view of the second substrate and a plan view of the facing surface thereof in this order from the left side; and FIG. 8(C) shows a top view and a bottom view of a laminated body in this order from the left side.

FIG. 9 schematically shows the first substrate and the second substrate that have patterning portions, of an example of the present invention: FIG. 9(A) shows a side view of the first substrate, a plan view of the facing surface thereof, and a plan view of the opposite surface thereof in this order from the left side; FIG. 9(B) shows a side view of the second substrate and a plan view of the facing surface thereof in this order from the left side; and FIG. 9(C) shows a top view and a bottom view of a laminated body in this order from the left side.

FIG. 10 schematically shows the first substrate and the second substrate that have patterning portions, of an example of the present invention: FIG. 10(A) shows a side view of the first substrate, a plan view of the facing surface thereof, and a plan view of the opposite surface thereof in this order from the left side; FIG. 10(B) shows a side view of the second substrate and a plan view of the facing surface thereof in this order from the left side; and FIG. 10(C) shows a top view and a bottom view of a laminated body in this order from the left side.

FIG. 11 schematically shows a laminated body assembly kit including a third substrate, of an example of the present invention: in FIG. 11(A), a side view of the first substrate is shown on the left side, and a plan view of the opposite surface of the first substrate is shown on the right side; in FIG. 11(B), a side view of the second substrate is shown on the left side, and a plan view of the facing surface of the second substrate is shown on the right side; and FIG. 11(C) is a side view of a laminated body.

FIG. 12 schematically shows a laminated body assembly kit including a third substrate, of an example of the present invention: in FIG. 12(A), a side view of the first substrate is shown on the left side, and a plan view of the opposite surface of the first substrate is shown on the right side; in FIG. 12(B), a side view of the second substrate is shown on the left side, and a plan view of the facing surface of the second substrate is shown on the right side; in FIG. 12(C), a side view of the third substrate is shown, and a plan view of a facing surface of the third substrate is shown on the right side; and in FIG. 12(D), a side view of a laminated body is shown on the left side, and a plan view of the laminated body is shown on the right side.

### DESCRIPTION OF EMBODIMENTS

In the laminated body assembly kit of the present invention, for example, the first substrate and the second substrate are transparent substrates.

In the laminated body assembly kit of the present invention, for example, the first substrate has two or more of the lens portions, and the second substrate has two or more of the alignment mark portions.

In the laminated body assembly kit of the present invention, for example, on a facing surface of the second substrate, a total area of the alignment mark portion is 3% or less of an area of the entire second substrate.

In the laminated body assembly kit of the present invention, for example, the lens portion has a spherical or aspherical surface.

In the laminated body assembly kit of the present invention, for example, the lens portion is a cylindrical lens.

In the laminated body assembly kit of the present invention, for example, the alignment mark portion has a quadrangular shape in a plan view.

In the laminated body of the present invention, for example, the first substrate and the second substrate are transparent substrates.

In the laminated body of the present invention, for example, the first substrate has two or more of the lens portions, and the second substrate has two or more of the alignment mark portions.

In the laminated body of the present invention, for example, on a facing surface of the second substrate, a total area of the alignment mark portion is 3% or less of an area of the entire second substrate.

In the laminated body of the present invention, for example, the lens portion has a spherical or aspherical surface.

In the laminated body of the present invention, for example, the lens portion is a cylindrical lens.

In the laminated body of the present invention, for example, the alignment mark portion has a quadrangular shape in a plan view.

In the manufacturing method of the present invention, for example, the alignment mark portion has a quadrangular shape in a plan view, the first substrate and the second substrate are aligned by being moved in directions of two axes that are orthogonal to each other, and the two axes are parallel to respective pairs of opposing sides of the quadrangular shape.

Hereinafter, a laminated body assembly kit with an alignment function, a laminated body, and a method for manufacturing a laminated body, of the present invention will be described using the drawings and the like. In the drawings, the same portions are denoted by the same reference numerals. Moreover, unless otherwise specified, descriptions of each embodiment can be applied to other embodiments.

The laminated body of the present invention can be obtained using the laminated body assembly kit of the present invention or by performing the manufacturing method of the present invention. For this reason, the following description can be applied to each of the aspects of the present invention, for example.

The laminated body assembly kit and the method for manufacturing a laminated body, of the present invention can be used, without limitation, in the case where a laminated body is formed by aligning two or more substrates with each other. Also, the field to which the present invention is applicable is not particularly limited, and the present invention can be used in the case where a laminated body is formed by aligning two or more substrates with each other as described above. A specific example thereof is a case where substrates having, for example, patterning portions (portions subjected to patterning) on each other's facing surfaces, each facing the other substrate, are laminated together. For example, compared with a case where only the facing surface of one substrate has a patterning portion, more complex patterning of a laminated body is possible when two substrates have patterning portions on their facing surfaces and the two substrates are laminated together facing each other. The type of treatment used for the patterning is not particularly limited, and examples thereof include hydrophilic treatment, hydrophobic treatment, formation of a circuit such as a conductive film, formation of protrusions and recesses such as a flow channel, and the like. In this case, patterning portions are also referred to as functional portions, for example. For example, inkjet printing, screen printing, and the like can be used to form a conductive film. With these printing techniques, a high-density pattern portion can be formed on the facing surfaces of the substrates, and furthermore, a pattern portion and the above-described alignment mark portion can also be printed in the same step. Thus, the position accuracy of the pattern portion and the alignment mark portion can be improved. The higher the density of the pattern portion is, the more important the precision of alignment of the two substrates is. According to the present invention, alignment can be easily performed as described above, and therefore, the present invention is extremely useful in producing a laminated body having a high-density pattern portion.

Laminated Body Assembly Kit with Alignment Function

As described above, the laminated body assembly kit of the present invention includes a first substrate and a second substrate that are to be laminated together,
wherein the first substrate has a lens portion on a surface thereof opposite to a facing surface thereof that faces the second substrate,
the second substrate has an alignment mark portion on at least one surface thereof,
the first substrate and the second substrate are respectively provided with the lens portion and the alignment mark portion such that, in a set laminated state, the alignment mark portion of the second substrate is located at a focal position of the lens portion of the first substrate, and
an image of the alignment mark portion that is formed in the lens portion in the set laminated state is an image indicating that the set laminated state has been achieved.

In the present invention, the number of substrates to be laminated is not particularly limited, and may be two or more, or three or more, for example. In the present invention, at least two substrates to be aligned are referred to as a first substrate and a second substrate.

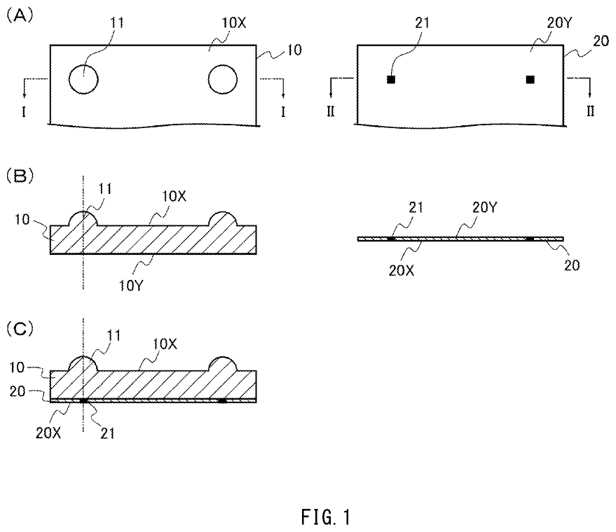

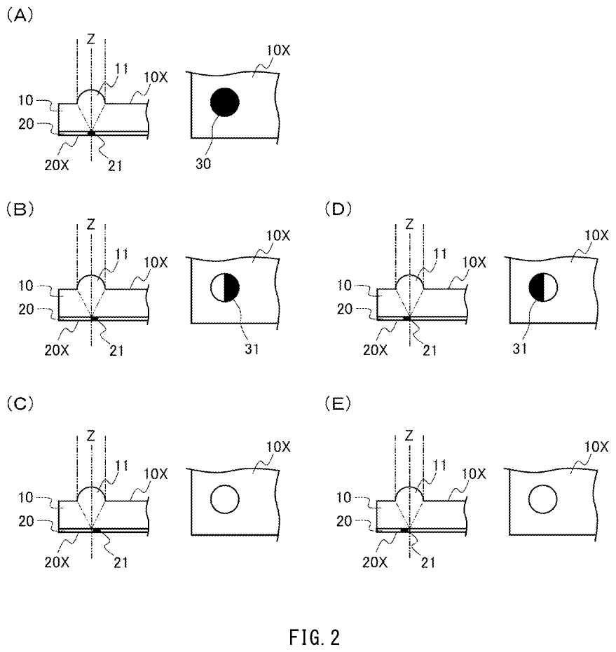

In the present invention, the first substrate has a lens portion on a surface thereof opposite to a facing surface thereof that faces the second substrate, and the second substrate has an alignment mark portion on at least one of a facing surface thereof that faces the first substrate and a surface thereof opposite to the facing surface. A relationship between the lens portion of the first substrate and the alignment mark portion of the second substrate will be described using FIGS. 1 and 2 as an example. Note that, in the following description, the size, shape, and the like of the lens portion and the alignment mark portion are given for illustrative purposes only, and should not be interpreted as limiting the present invention.

FIG. 1 schematically shows the first substrate and the second substrate, as well as the laminated body of the first substrate and the second substrate. In FIG. 1, FIG. 1(A) shows plan views of a portion of the first substrate 10 and the second substrate 20 when viewed from above, or more specifically, a plan view of a surface 10X of the first substrate 10 opposite to a facing surface 10Y that faces the second substrate 20 and a plan view of a facing surface 20Y of the second substrate 20 that faces the first substrate 10. FIG. 1(B) shows a cross-sectional view of the first substrate 10 in FIG. 1(A) when viewed from the direction I-I and a cross-sectional view of the second substrate 20 in FIG. 1(A) when viewed from the direction II-II. FIG. 1(C) is a cross-sectional view showing a state in which the first substrate 10 and the second substrate 20 are laminated together, when viewed from the same direction as in FIG. 1(B). As shown in FIG. 1, the first substrate 10 has a lens portion 11 on an upper surface, that is, the surface 10X opposite to the facing surface 10Y that faces the second substrate 20, and the second substrate 20 has an alignment mark portion 21 on an upper surface, that is, the facing surface 20Y that faces the first substrate 10. In the present embodiment, the first substrate 10 is a transparent substrate, and the lens portion 11 has a circular shape in a plan view and has a spherical surface shape that protrudes upward, while the second substrate 20 is a transparent substrate, and the alignment mark portion 21 thereof is a black square. Note that, although FIG. 1 shows a form in which a black quadrangular prism is embedded in a through hole of the second substrate 20, and a surface of the quadrangular prism that is exposed in the upper surface of the second substrate 20 serves as the alignment mark portion 21, the present invention is not limited to this form. As will be described later, the alignment mark portion 21 may also be a mark that is printed onto the surface of the second substrate 20, for example.

FIG. 2 shows images (also referred to as virtual images) of the alignment mark portion 21 that are formed in the lens portion 11 when the first substrate 10 and the second substrate 20 are laminated together with the facing surface 10Y and the facing surface 20Y facing each other and the lens portion 11 of the first substrate 10 and the alignment mark portion 21 of the second substrate 20 are moved in a planar direction. Specifically, in each of FIGS. 2(A) to 2(E), a cross-sectional view showing a laminated state of the first substrate 10 and the second substrate 20 is shown on the left side, and a plan view showing an image of the alignment mark portion 21 that is formed in the lens portion 11 of the first substrate 10 is shown on the right side. As shown in FIG. 2(A), when the lens portion 11 is seen from the direction of a normal line (Z in FIG. 2) thereto, the alignment mark portion 21 of the second substrate 20 is located at the focal position of the lens portion 11. Therefore, a perfect circle-shaped image 30 is formed as the shape of the alignment mark portion 21 is enlarged in (projected onto) the lens portion 11, and this image can be detected.

However, as shown in FIG. 2(B), if the position of the alignment mark portion 21 of the second substrate 20 is shifted rightward from the focal position of the lens portion 11, the alignment mark portion 21 cannot be fully imaged, and therefore, for example, a semicircular image 31, formed as only a portion of the alignment mark portion 21 is enlarged, is detected. As shown in FIG. 2(C), if the position of the alignment mark portion 21 of the second substrate 20 is shifted further rightward from the focal position of the lens portion 11, no image of the alignment mark portion 21 can be detected. As shown in FIG. 2(D), if the position of the alignment mark portion 21 of the second substrate 20 is shifted leftward, the alignment mark portion 21 cannot be fully imaged, and therefore, for example, a semicircular image 31, formed as only a portion of the alignment mark portion 21 is enlarged, is detected. As shown in FIG. 2(E), if the position of the alignment mark portion 21 of the second substrate 20 is shifted further leftward from the focal position of the lens portion 11, no image of the alignment mark portion 21 can be detected.

That is to say, it can be said that, only when the first substrate 10 and the second substrate 20 are in a specific positional relationship, will the alignment mark portion 21 be fully imaged in the lens portion 11. For this reason, in the laminated body assembly kit of the present invention, the first substrate is provided with the lens portion and the second substrate is provided with the alignment mark portion such that the alignment mark portion of the second substrate is located at the focal position of the lens portion of the first substrate in a set laminated state. Then, an image of the alignment mark portion that is formed in the lens portion in the set laminated state is used as an image indicating that the set laminated state has been achieved. Thus, the laminated body assembly kit of the present invention is configured such that it can be judged that the positions of the first substrate and the second substrate are aligned when the first substrate and the second substrate are placed facing each other, and an image indicating the set laminated state can be confirmed in the lens portion of the first substrate. Taking the case of the first substrate 10 and the second substrate 20 shown in FIG. 1 as an example, the first substrate 10 and the second substrate 20 are placed facing each other, and then, while the two substrates are moved in a planar direction, an image is detected from the lens portion 11 of the first substrate 10. Then, in the cases of FIGS. 2(B) to 2(E), the first substrate 10 and the second substrate 20 are moved, and when the image 30 shown in FIG. 2(A) is confirmed, it can be judged that the two substrates are aligned in the set laminated state.

As described above, according to the present invention, the first substrate and the second substrate can be easily aligned simply by checking the image of the alignment mark portion of the second substrate that is formed in the lens portion of the first substrate. According to the present invention, even alignment with a precision of about 0.01 mm, for example, is possible.

In the present invention, the “set laminated state” refers to a preset laminated state of the first substrate and the second substrate, and is, for example, a laminated state that enables the laminated body to achieve an intended function. Here, as a specific example, construction of a laminated body having a conductive pattern and a flow channel pattern, such as those described later, will be described by way of example. To construct a structure having the conductive pattern and the flow channel pattern as a laminated body, first, the positional relationship between the conductive pattern and the flow channel pattern is determined, and the conductive pattern is provided on one of the substrates (e.g., first substrate), and the flow channel pattern is provided on the other substrate (e.g., second substrate). What is important here is to laminate the first substrate and the second substrate such that the conductive pattern and the flow channel pattern are in the determined positional relationship. Therefore, in this specific example, the laminated state that satisfies the predetermined positional relationship is the “set laminated state”. The first substrate and the second substrate are provided with the lens portion and the alignment mark portion, respectively, such that, for example, an image 30 such as that shown in FIG. 2(A) is formed when the two substrates are laminated in the determined positional relationship. Note that the foregoing description is given by way of example only, and should not be interpreted as limiting the present invention.

In the first substrate, the lens portion is formed of a transparent member, for example. Only the lens portion of the first substrate may be formed of a transparent member, or the entire first substrate may be formed of a transparent member. The transparent member may be, for example, a translucent member, and examples thereof include resin, glass, and the like. Examples of the resin include polycarbonate (PC), acrylic resins (e.g., polymethyl methacrylate (PMMA)), cycloolefin polymers (COPs), cycloolefin copolymers (COCs), and the like.

The second substrate is not particularly limited, and may be a transparent substrate, for example, or may be a substrate other than a transparent substrate. In the present invention, it is sufficient that, when detecting the alignment mark portion of the second substrate in the lens portion of the first substrate, the alignment mark portion of the second substrate can be optically distinguished from the other regions of the second substrate. In the case where the second substrate is a transparent substrate as described above, the member constituting the transparent substrate is not particularly limited, and may be similar to those for the first substrate, for example. Moreover, in the case where the second substrate is a substrate other than a transparent substrate as described above, the substrate may be a colored substrate, for example. The colored substrate can be molded using a colored resin obtained by adding a colorant to a resin such as those described above. The resin to which the colorant is added may be similar to those described above, for example. Examples of the colorant include a masterbatch, a dry color, and the like.

There is no particular limitation on the method for forming the alignment mark portion of the second substrate, and the alignment mark portion can be formed through inkjet printing, screen printing, or the like, for example. Moreover, as described above, according to the present invention, alignment can be checked based on the image of the alignment mark portion that is formed in the lens portion of the first substrate, and therefore, fitting or the like, for example, which has conventionally been required, is no longer necessary. For this reason, in the present invention, the second substrate does not need to have a thickness, a strength, and the like that have been required for handling in a conventional method, for example. In the present invention, the thickness and the strength of the second substrate are not particularly limited, and, for example, a plate, a film, a sheet, and the like can also be used.

There is no limitation on the combination of the color of the second substrate and the color of the alignment mark portion of the second substrate, and, for example, a combination of colors that can be distinguished from each other is preferable. When the color of the second substrate is transparent or white, for example, the color of the alignment mark portion is preferably black, for example.

The number of lens portions of the first substrate and the number of alignment mark portions of the second substrate are not particularly limited, and each may be two or more, three or more, or four or more, for example. It is preferable that the number of lens portions and the number of alignment mark portions are equal in order that the lens portions and the alignment mark portions correspond one-to-one during the alignment. The number of lens portions can be appropriately determined depending on, for example, the shape and the like of the first substrate and the second substrate to be aligned.

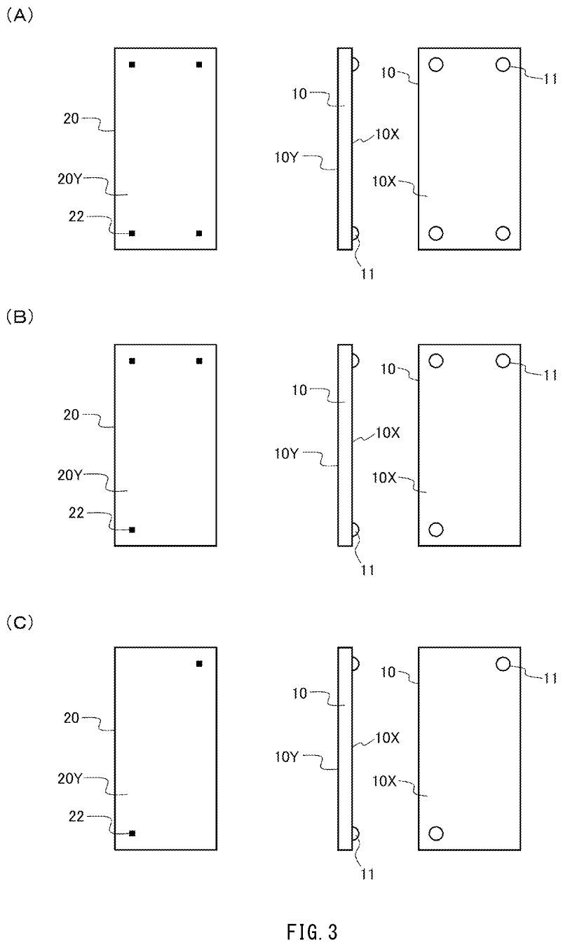

FIG. 3 shows examples of the number and the positions of lens portions of the first substrate and the number and the positions of alignment mark portions of the second substrate. Alignment mark portions 22 shown in FIG. 3 are in a form that does not have a substantial height on the facing surface 20Y of the second substrate 20. FIG. 3 is given for illustrative purposes only, and, for example, the number and the positions of the lens portions and the number and the positions of the alignment mark portions, as well as the sizes and shapes of various portions shown should not be interpreted as limiting the present invention.

FIG. 3 schematically shows examples of the first substrate and the second substrate. FIGS. 3(A), 3(B), and 3(C) show different numbers of lens portions and alignment mark portions, and in each of FIGS. 3(A), 3(B), and 3(C), a plan view of the facing surface of the second substrate is shown on the left side, a plan view of the opposite surface of the first substrate is shown on the right side, and a side view of the first substrate is shown in the middle. FIG. 3(A) shows a form in which a single circular lens portion 11 is provided in each of the four corners of the opposite surface 10X of the first substrate 10, and a single square alignment mark portion 22 is provided in each of the four corners of the facing surface 20Y of the second substrate 20. FIG. 3(B) shows a form in which three corners of the opposite surface 10X of the first substrate 10 are each provided with a single circular lens portion 11, and three corners of the facing surface 20Y of the second substrate 20 are each provided with a single square alignment mark portion 22. FIG. 3(C) shows a form in which two opposing corners of the opposite surface 10X of the first substrate 10 are each provided with a single circular lens portion 11, and two opposing corners of the facing surface 20Y of the second substrate 20 are each provided with a single square alignment mark portion 22. The lens portions 11 of the first substrate 10 and the alignment mark portions 22 of the second substrate 20 are formed at positions where the lens portions 11 and the respective alignment mark portions 22 oppose each other when the first substrate 10 and the second substrate 20 are laminated together.

The shape of a lens portion of the first substrate is not particularly limited, and the lens portion of the first substrate may have, for example, the shape of a lens having a circular shape in a plan view or the shape of a cylindrical lens extending in a planar direction. In the former case, as shown in FIGS. 1 and 2 by way of example, the lens portion has, for example, a circular shape in a plan view and has a spherical or aspherical surface shape. The aspherical surface shape refers to a shape whose curvature continuously or discontinuously decreases (becomes more gentle) from the apex toward the outer periphery thereof, for example. The cylindrical lens of the latter case has, for example, a structure obtained by dividing a cylinder along its axial direction and has a protruding portion extending in the axial direction, and a curved surface of the protruding portion constitutes a lens surface.

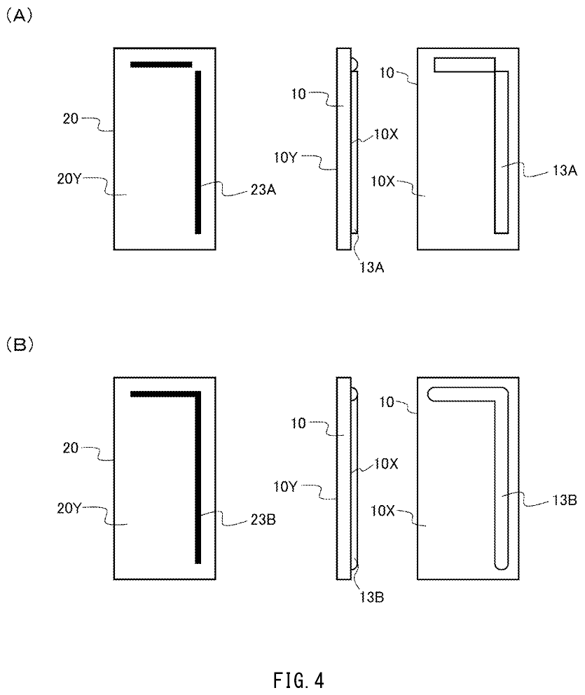

FIG. 4 shows examples of a case where lens portions of the first substrate are cylindrical lenses. Note that FIG. 4 is given for illustrative purposes only, and should not be interpreted as limiting the present invention.

FIG. 4 schematically shows examples of the first substrate and the second substrate. In each of FIGS. 4(A) and 4(B), a plan view of the facing surface of the second substrate is shown on the left side, a plan view of the opposite surface of the first substrate is shown on the right side, and a side view of the first substrate is shown in the middle. FIG. 4(A) shows a form in which a single lens portion 13A (cylindrical lens) is provided along each of one long side and one short side of the opposite surface 10X of the first substrate 10, and a single linear alignment mark portion 23A is provided along each of one long side and one short side of the facing surface 20Y of the second substrate 20. FIG. 4(B) shows a form in which a single continuous lens portion 13B (cylindrical lens) is provided extending along one long side and one short side of the opposite surface 10X of the first substrate 10, and a single continuous alignment mark portion 23B is provided extending along one long side and one short side of the facing surface 20Y of the second substrate 20. The lens portions 13A and 13B of the first substrate 10 and the alignment mark portions 23A and 23B of the second substrate 20 are formed at positions where the lens portions 13A and 13B and the respective alignment mark portions 23A and 23B oppose each other when the first substrate 10 and the second substrate 20 are laminated together.

A lens portion of the first substrate may have a single lens per lens portion as shown in FIGS. 1 to 3, for example, or may have a plurality of lenses per lens portion. In the latter case, the lens portion can also be said to be, for example, a lens array constituted by a plurality of lenses. When the lens portion is a lens array as described above, an alignment mark portion of the second substrate that is located at a position corresponding to the lens array may have a plurality of marks corresponding to the plurality of lenses constituting the lens array, for example.

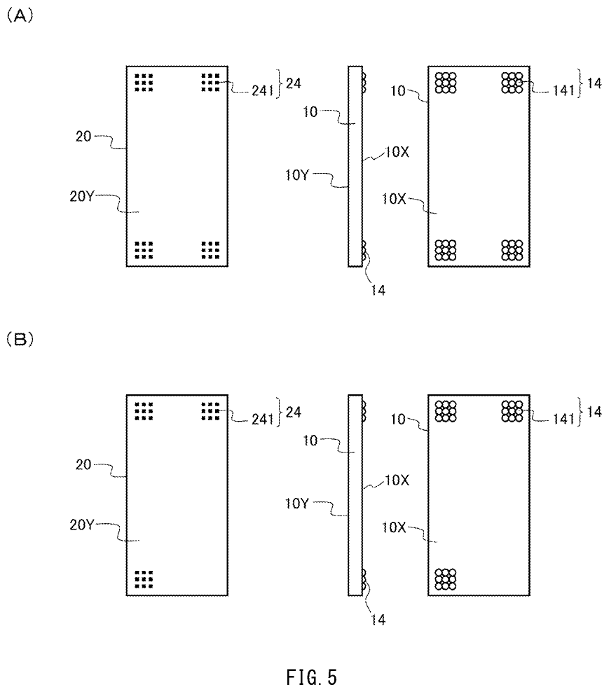

FIG. 5 shows examples of a case where lens portions of the first substrate are lens arrays. Note that FIG. 5 is given for illustrative purposes only, and should not be interpreted as limiting the present invention.

FIG. 5 schematically shows examples of the first substrate and the second substrate. In each of FIGS. 5(A) and 5(B), a plan view of the facing surface of the second substrate is shown on the left side, a plan view of the opposite surface of the first substrate is shown on the right side, and a cross-sectional view of the first substrate is shown in the middle. FIG. 5(A) shows a form in which a lens portion 14 (lens array) constituted by a plurality of lenses 141 is provided in each of the four corners of the opposite surface 10X of the first substrate 10, and an alignment mark portion 24 constituted by a plurality of quadrangular marks 241 is provided in each of the four corners of the facing surface 20Y of the second substrate 20. FIG. 5(B) shows a form in which three corners of the opposite surface 10X of the first substrate 10 are each provided with a lens portion 14 (lens array) constituted by a plurality of lenses 141, and three corners of the facing surface 20Y of the second substrate 20 are each provided with an alignment mark portion 24 constituted by a plurality of quadrangular marks 241.

In FIG. 5, each lens portion 14 of the first substrate 10 is a lens array in which nine lenses 141 are formed consecutively in three rows and three columns. The number of lenses 141 included in a lens portion 14 is not limited to this and may be two or more, for example, and it is preferable that the plurality of lenses 141 are arranged such that, for example, the central axes of the lenses in a single row or column are lined up on the same line. It is preferable that the plurality of lenses 141 included in the same lens portion 14 have the same shape, for example.

In FIG. 5, each mark portion 24 of the second substrate 20 is constituted by nine marks 241 that are formed consecutively in three rows and three columns at regular intervals. The number of marks 241 included in a mark portion 24 is not limited to this and may be the same as the number of lenses 141 of a lens portion 14, for example. It is preferable that the marks 241 included in the same mark portion 24 have the same shape, for example.

The pitch of the lenses 141 in a lens portion 14 may be constant or may vary, for example, and is preferably constant. Moreover, the pitch of the marks 241 in a mark portion 24 may be constant or may vary, for example, and is preferably constant. The pitch of the lenses 141 in a lens portion 14 and the pitch of the marks 241 in a mark portion 24 may be the same or different from each other, and furthermore, are preferably different from each other from the viewpoint of enabling improvement of the position accuracy and quantitative determination of the amount of positional deviation.

The shape of an alignment mark portion of the second substrate is not particularly limited and can be appropriately set depending on the shape of the lens portion of the first substrate, for example. The number of marks included in the alignment mark portion is not particularly limited and may be one or two or more, for example. Examples of the shape of the alignment mark portion include circular shapes, such as a perfect circle and an ellipse, polygonal shapes, linear shapes, and the like, and examples of the polygonal shapes include quadrangles, such as a square and a rectangle, and the like. The shape of the alignment mark portion means the shape of a mark that forms the alignment mark portion, and is the shape of the alignment mark portion itself when the alignment mark portion is formed by a single mark, or is the shape of each mark when the alignment mark portion is formed by a plurality of marks. Note that there is no particular limitation on the shape of an entire alignment mark portion formed by a plurality of marks, that is, an outer shape containing the plurality of marks.

It is preferable that the alignment mark portion has, for example, a quadrangular shape in a plan view, because an image thereof at a boundary portion has a straight line. When an image at the boundary portion has a straight line, this means that, for example, the shape of a boundary of a virtual image formed in the lens portion has a straight line. Usually, an adjustment platform is used in aligning the first substrate and the second substrate that face each other. The adjustment platform is capable of moving in, for example, the directions of two axes (X axis and Y axis) that are orthogonal to each other, and therefore, alignment can be performed by moving at least one of the first substrate and the second substrate in a planar direction in either one of the directions of the two orthogonal axes. Thus, when the alignment mark portion has a quadrangular shape, a virtual image has straight lines, for example, and therefore, alignment can be performed with higher accuracy in a simpler manner by arranging the two pairs of opposing sides respectively along the two orthogonal axes, which are the moving directions.

The alignment mark portion may be a two-dimensional mark or a three-dimensional mark, for example. The two-dimensional mark refers to, for example, a mark that does not have a substantial height (e.g., has a height of less than 50 μm) on the second substrate, or specifically, may be a mark that can be identified by the color of the alignment mark portion on the second substrate, for example. In this case, the alignment mark portion can be formed through printing onto the second substrate, for example. The three-dimensional mark refers to, for example, a mark with a three-dimensional structure that has a substantial height (e.g., a height of 50 μm or more) on the second substrate, or specifically, may be a mark that can be identified by the three-dimensional shape of the alignment mark portion on the second substrate, for example. Examples of the three-dimensional shape include a protrusion and recess shape, an edge, and the like on the second substrate.

It is sufficient that the alignment mark portion is arranged on at least one surface of the second substrate. As specific examples, the alignment mark portion, for example, may be arranged on the facing surface of the second substrate that faces the first substrate, may be arranged on the surface opposite to the first substrate, or may be arranged on both surfaces.

In the case where the alignment mark portion is arranged on the facing surface of the second substrate, the position of the alignment mark portion is not particularly limited, and, for example, any position can be set in a region excluding a patterning portion such as those described above. The proportion of the alignment mark portion on the facing surface of the second substrate is not particularly limited. The upper limit of the proportion of the total area of the alignment mark portion on the facing surface is, for example, 3% or less, or 1% or less. The upper limit of the planar area of the alignment mark portion is, for example, 0.01 mm² or less, or 0.0001 mm² or less.

According to the present invention, the alignment mark portion can be imaged and thereby observed in the lens portion in an enlarged manner. Therefore, even when the proportion of the total area of the alignment mark portion is, for example, 3% or less of the area of the entire second substrate, the first substrate and the second substrate can be aligned with high accuracy. Moreover, according to the present invention, the area of the alignment mark portion can be reduced to a small area. Therefore, for example, the degree of freedom of arrangement of a functional portion, such as a conductive film, to be arranged on the second substrate can be increased.

As described above, in the case where the first substrate and the second substrate are laminated together, the patterning portions are formed on the facing surfaces of the two substrates, for example. Thus, if the alignment mark portion is formed on the opposite surface of the second substrate, patterning can be freely performed over the entire region of the facing surface thereof, for example.

In the case where the alignment mark portion is arranged on the opposite surface of the second substrate, the position of the alignment mark portion is not particularly limited, and, for example, the alignment mark portion can be formed at any position where the alignment mark portion can be seen from the facing surface side of the second substrate. The proportion of the alignment mark portion on the opposite surface of the second substrate is not particularly limited, and may be similar to that described above, for example.

The present invention may further include one or more substrates, for example. As a specific example, the present invention may further include a third substrate having a lens portion or a third substrate having an alignment mark portion.

In the case where the present invention includes a third substrate having the lens portion, a form is conceivable, for example, in which the first substrate having the lens portion and the third substrate having the lens portion are laminated to the two surfaces of the second substrate having the alignment mark portion. The lens portion of the third substrate is, for example, a lens portion corresponding to the alignment mark portion of the second substrate as is the case with the first substrate. The second substrate has the alignment mark portion on at least one surface thereof. The first substrate has the lens portion on the surface opposite to the second substrate, and the first substrate is laminated such that the facing surface thereof faces one of the surfaces of the second substrate. While the first substrate is laminated to one of the surfaces of the second substrate, for example, another substrate can be further laminated to the other surface of the second substrate. Therefore, when the lens portion is arranged on the third substrate serving as the other substrate, it is possible to further laminate the third substrate on the surface of the second substrate that is on the opposite side to the surface on which the first substrate is laminated, and to perform alignment using the alignment mark portion of the second substrate. In this case, the first substrate having the lens portion and the third substrate having the lens portion are individually aligned on the two surfaces of the second substrate using the same alignment mark of the second substrate. For this purpose, it is preferable that the first substrate, the second substrate, and the third substrate are transparent substrates, for example.

In the case where the present invention includes a third substrate having the alignment mark portion, a form is conceivable, for example, in which the second substrate having the alignment mark portion and the third substrate are laminated in this order on the surface of the first substrate that is opposite to the surface on which the lens portion is formed. In this form, it is preferable that the first substrate has a lens portion corresponding to the alignment mark portion of the second substrate and a lens portion corresponding to the alignment mark portion of the third substrate. The lens shape and the lens thickness of each lens portion can be appropriately set such that, for example, the lens portion can be focused on a corresponding mark portion. It is preferable that the second substrate and the third substrate respectively have the mark portions at positions where the mark portions do not overlap when the two substrates are laminated, and the second substrate is a substrate that allows the mark portion of the third substrate to be seen from the facing surface of the second substrate that faces the first substrate. Since the lens portions of the first substrate respectively correspond to the mark portion of the second substrate and the mark portion of the third substrate, the lens portions can be aligned with the respective mark portions of the second substrate and the third substrate.

According to the present invention, even when three substrates are used as described above, alignment can be performed with excellent accuracy. Therefore, providing functional portions on facing surfaces of the three substrates makes it possible to, for example, design more complex functional portions for a laminated body in which the three substrates are laminated together.

As described above, the first substrate and the second substrate respectively have the lens portion and the alignment mark portion such that, in the set laminated state, the alignment mark portion of the second substrate is located at the focal position of the lens portion of the first substrate. The laminated body assembly kit of the present invention is a kit for making it easy to align the first substrate and the second substrate in the set laminated state, and the laminated state in which the substrates are correctly aligned can be set as desired. Moreover, the focal position of the lens portion of the first substrate can be set depending on, for example, the thickness of the first substrate, the refractive index of the lens portion, and the like, and the position of the alignment mark portion of the second substrate that is located at the focal position can be appropriately set depending on, for example, the distance from the lens portion to the alignment mark portion, the thickness of the second substrate, and the like.

### Laminated Body and Method for Manufacturing Laminated Body

As described above, a laminated body of the present invention includes a first substrate and a second substrate,
wherein the first substrate has a lens portion on a surface thereof opposite to a facing surface thereof that faces the second substrate,
the second substrate has an alignment mark portion on at least one surface thereof,
the first substrate and the second substrate are laminated together such that the lens portion of the first substrate and the alignment mark portion of the second substrate are located opposing each other, and
an image of the alignment mark portion of the second substrate that is formed in the lens portion is an image that is formed when the alignment mark portion is located at a focal position of the lens portion.

A method for manufacturing a laminated body of the present invention uses the laminated body assembly kit with an alignment function of the present invention and includes:
placing the first substrate and the second substrate facing each other such that the lens portion and the alignment mark portion are located opposing each other,
aligning the first substrate and the second substrate with each other by adjusting an image of the alignment mark portion of the second substrate that is formed in the lens portion to an image that is formed when the alignment mark portion is located at a focal position of the lens portion, and
fixing the first substrate and the second substrate in this state.

The laminated body of the present invention can be manufactured in accordance with the manufacturing method of the present invention with use of the laminated body kit with an alignment function of the present invention.

As described above using FIGS. 1 and 2, in the laminated body assembly kit of the present invention, the first substrate is provided with a lens portion and the second substrate is provided with an alignment mark portion such that, in the set laminated state, the alignment mark portion of the second substrate is located at the focal position of the lens portion of the first substrate. Moreover, an image of the alignment mark portion that is formed in the lens portion when the alignment mark portion of the second substrate is located at the focal position of the lens portion of the first substrate is preset as a correct image in the set laminated state. Thus, the first substrate and the second substrate can be aligned in the set laminated state, and thereby an intended laminated body can be obtained, by performing the following process. That is to say, the first substrate and the second substrate are first placed facing each other such that the lens portion and the alignment mark portion are located opposing each other. Then, while the image of the alignment mark portion of the second substrate that is formed in the lens portion is being checked, at least one of the first substrate and the second substrate is moved so as to adjust the image to the correct image. Then, at the time when the correct image is confirmed, it can be judged that the first substrate and the second substrate are aligned in the set laminated state, and the first substrate and the second substrate can be fixed in this laminated state. In this manner, according to the present invention, alignment in the set laminated state can be easily achieved simply by checking the image of the alignment mark portion of the second substrate in the lens portion of the first substrate.

Hereinafter, as specific application examples of the present invention, a first substrate and a second substrate having patterning portions will be described by way of example. Note that, however, the present invention is not limited to these examples.

### Embodiment 1

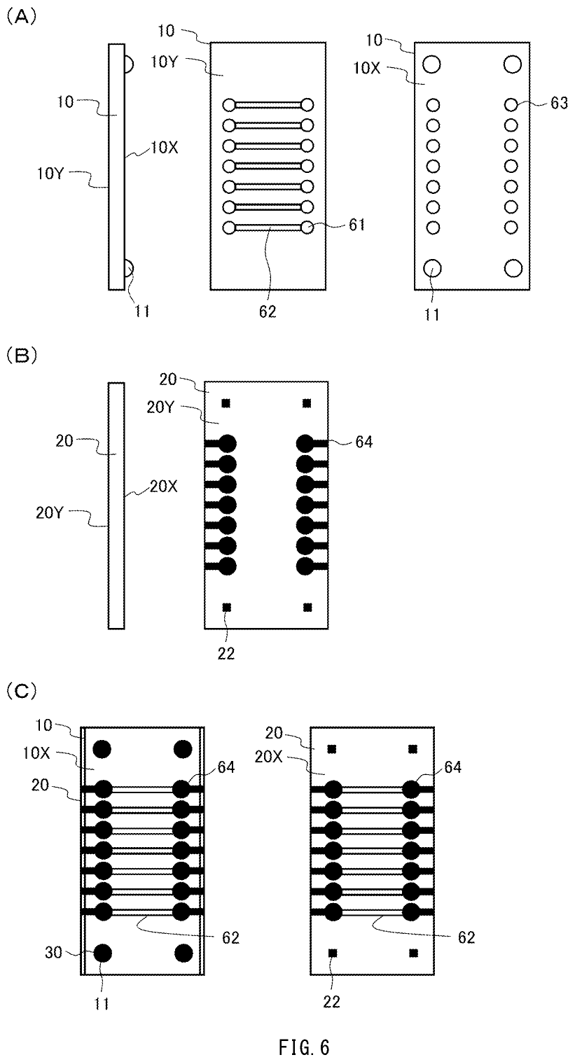

The present embodiment is a form in which the first substrate has a lens portion and a flow channel, and the second substrate has an alignment mark portion and a conductive film, and will be described using FIG. 6.

FIG. 6(A) schematically shows the first substrate 10, and a plan view of an upper surface, that is, the opposite surface 10X thereof is shown on the right side, a plan view of a lower surface, that is, the facing surface 10Y thereof is shown in the middle, and a side view thereof is shown on the left side. As in the case shown in FIG. 3(A), the first substrate 10 has a single lens portion 11 in each of the four corners of the opposite surface 10X. The facing surface 10Y of the first substrate 10 has annular recesses 61, as well as recesses 62 that are each in communication with a pair of recesses 61 at the two ends of the long side thereof. In FIG. 6(A), reference numeral 63 indicates a through hole. In the state of the laminated body, regions surrounded by the respective annular recesses 61 serve as liquid collecting portions in which a specimen is to be collected, and the recesses 62 serve as flow channels via which the liquid collecting portions are in communication with each other.

It is preferable that the lens portions 11, the recesses 61, and the recesses 62 of the first substrate 10 are formed at one time with the same processing such as injection molding, for example. The accuracy of the positional relationship of the various portions can be increased by forming the lens portions 11, the annular recesses 61, and the recesses 62 with the same processing. Furthermore, an additional step can be omitted during the manufacturing, and consequently, the process can be simplified.

FIG. 6(B) schematically shows the second substrate 20, and a plan view of an upper surface, that is, the facing surface 20Y thereof is shown on the right side, and a side view thereof is shown on the left side. As in the case shown in FIG. 3(A), the second substrate 20 has a single quadrangular alignment mark portion 22 in each of the four corners of the facing surface 20Y. The second substrate 20 further has conductive films 64 extending inward from the two ends of the second substrate 20 on its long sides and having circular inner ends. The circular ends of the conductive films 64 are arranged on the facing surface 20Y of the second substrate 20 such that, in the state of the laminated body, the circular ends are located at the respective liquid collecting portions.

It is preferable that the alignment mark portions 22 and the conductive films 64 of the second substrate 20 are formed at one time in the same step through printing or the like, for example. The accuracy of the positional relationship of the various portions, for example, can be increased even more by forming the alignment mark portions 22 and the conductive films 64 in the same step, and furthermore, an additional step can be omitted during the manufacturing, and consequently, the process can be simplified.

FIG. 6(C) schematically shows the laminated body in which the first substrate 10 and the second substrate 20 are laminated together. FIG. 6(C) shows an example in which the first substrate 10 and the second substrate 20 are transparent substrates, and a top view of the laminated body when viewed from the opposite surface 10X side of the first substrate 10 is shown on the left side, and a bottom view of the laminated body when viewed from the opposite surface 20X side of the second substrate 20 is shown on the right side. In the top view in FIG. 6(C), a state in which virtual images 30 of the alignment mark portions 22 of the second substrate 20 appear in the respective lens portions 11 of the first substrate 10 is indicated by solid circles.

The set laminated state of the first substrate 10 and the second substrate 20 is a state in which the circular ends of the conductive films 64 coincide with the respective liquid collecting portions surrounded by the recesses 61. The lens portions 11 and the alignment mark portions 22 are formed on the first substrate 10 and the second substrate 20, respectively, such that, in this state, the alignment mark portions 22 of the second substrate 20 are located at the focal positions of the lens portions 11 of the first substrate 10. Thus, at the time when, after the first substrate 10 and the second substrate 20 are placed facing each other, the images formed in the lens portions 11 of the first substrate 10 become the images 30 as shown in FIG. 2(A), for example, the first substrate 10 and the second substrate 20 are aligned in a predetermined laminated state. That is to say, when the substrates are aligned in the predetermined laminated state, the correct images 30 can be confirmed in the four lens portions 11 on the opposite surface 10Y of the first substrate 10 as shown in the top view on the left side in FIG. 6(C). In this state, the circular ends of the conductive films 64 coincide with the respective liquid collecting portions surrounded by the recesses 61.

Moreover, the length of the first substrate 10 in the direction along the short side thereof is shorter than the length of the second substrate 20 in the direction along the short side thereof. Therefore, as shown in the top view on the left side in FIG. 6(C), in the laminated state, the other ends (on the opposite side to the circular ends) of the conductive films 64 of the second substrate 20 are exposed, so that external leads can be connected to the other ends of the conductive films 64.

### Embodiment 2

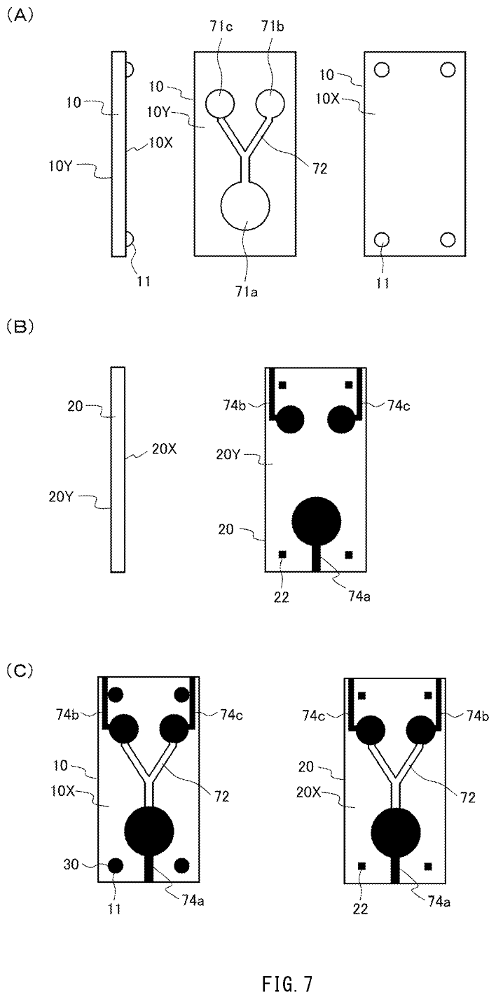

The present embodiment is a form in which the first substrate has a lens portion and a branching flow channel, and the second substrate has an alignment mark portion and a conductive film, and will be described using FIG. 7.

FIG. 7(A) schematically shows the first substrate 10, and a plan view of an upper surface, that is, the opposite surface 10X thereof is shown on the right side, a plan view of a lower surface, that is, the facing surface 10Y thereof is shown in the middle, and a side view thereof is shown on the left side. As in the case of Embodiment 1, the first substrate 10 has lens portions 11. The first substrate 10 has circular recesses 71a, 71b, and 71c, and a branching recess 72 that is in communication with these circular recesses. In the state of the laminated body, regions surrounded by the respective circular recesses 71a, 71b, and 71c serve as liquid collecting portions in which a specimen is to be collected, and the recess 72 serves as a branching flow channel via which the liquid collecting portions are in communication with each other.

It is preferable that the lens portions 11 and the circular recesses 71a, 71b, and 71c of the first substrate 10 are formed through the same processing, as in the case of Embodiment 1.

FIG. 7(B) schematically shows the second substrate 20, and a plan view of an upper surface, that is, the facing surface 20Y thereof is shown on the right side, and a side view thereof is shown on the left side. The second substrate 20 has alignment mark portions 22 similar to those of Embodiment 1. The second substrate 20 further has conductive films 74a, 74b, and 74c extending inward from the two ends of the second substrate 20 on its short sides and having circular inner ends. The circular ends of the conductive films 74a, 74b, and 74c are arranged such that, in the state of the laminated body, the circular ends are located at the respectively corresponding liquid collecting portions.

It is preferable that the alignment mark portions 22 and the circular conductive films 74a, 74b, and 74c of the second substrate 20 are formed in the same step, as in the case of Embodiment 1.

FIG. 7(C) schematically shows the laminated body in which the first substrate 10 and the second substrate 20 are laminated together. FIG. 7(C) shows an example in which the first substrate 10 and the second substrate 20 are transparent substrates, and a top view of the laminated body when viewed from the opposite surface 10X side of the first substrate 10 is shown on the left side, and a bottom view of the laminated body when viewed from the opposite surface 20X side of the second substrate 20 is shown on the right side. In the top view in FIG. 7(C), a state in which virtual images 30 of the alignment mark portions 22 of the second substrate 20 appear in the respective lens portions 11 of the first substrate 10 is indicated by solid circles. Regarding the alignment, a similar description to that of Embodiment 1 above applies.

### Embodiment 3

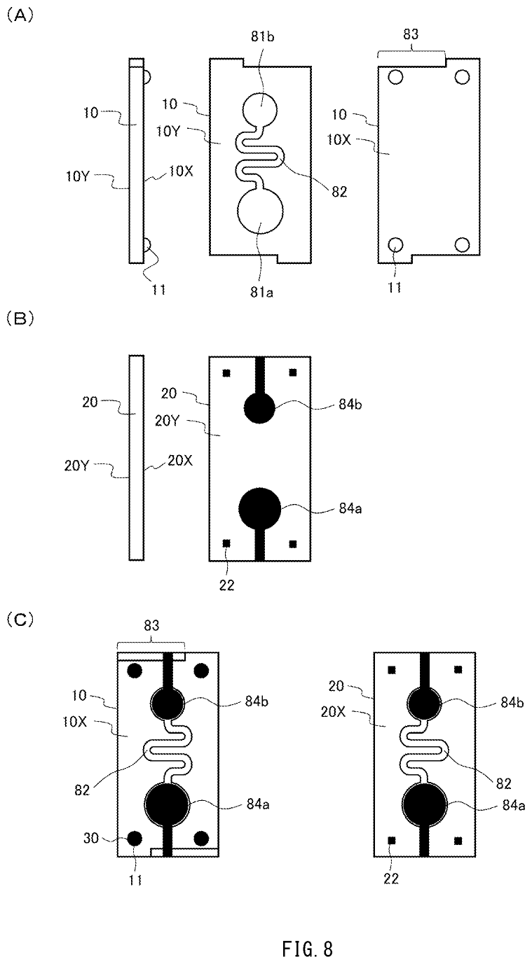

The present embodiment is a form in which the first substrate has a lens portion and a cut-away portion, and the second substrate has an alignment mark portion and a conductive film, and will be described using FIG. 8.

FIG. 8(A) schematically shows the first substrate 10, and a plan view of an upper surface, that is, the opposite surface 10X thereof is shown on the right side, a plan view of a lower surface, that is, the facing surface 10Y thereof is shown in the middle, and a side view thereof is shown on the left side. As in the case of Embodiment 1, the first substrate 10 has lens portions 11. The first substrate 10 has circular recesses 81a and 81b, and a winding recess 82 that is in communication with these circular recesses. In the state of the laminated body, regions surrounded by the respective circular recesses 81a and 81b serve as liquid collecting portions in which a specimen is to be collected, and the recess 82 serves as a flow channel via which the liquid collecting portions are in communication with each other. Moreover, the first substrate 10 has cut-away portions 83 at diagonal positions on the short sides thereof. The cut-away portions 83 constitute indicators that tell the right side and the wrong side of the first substrate 10 when laminating the first substrate 10 to the second substrate 20.

It is preferable that the lens portions 11 and the circular recesses 81a and 81b of the first substrate 10 are formed through the same processing, as in the case of Embodiment 1.

FIG. 8(B) schematically shows the second substrate 20, and a plan view of an upper surface, that is, the facing surface 20Y thereof is shown on the right side, and a side view thereof is shown on the left side. The second substrate 20 has alignment mark portions 22 similar to those of Embodiment 1. The second substrate 20 further has conductive films 84a and 84b extending inward from the two ends of the second substrate 20 on its short sides and having circular inner ends. The circular ends of the conductive films 84a and 84b are arranged such that, in the state of the laminated body, the circular ends are located at the respectively corresponding liquid collecting portions.

It is preferable that the alignment mark portions 22 and the circular conductive films 84a and 84b of the second substrate 20 are formed in the same step, as in the case of Embodiment 1.

FIG. 8(C) schematically shows the laminated body in which the first substrate 10 and the second substrate 20 are laminated together. FIG. 8(C) shows an example in which the first substrate 10 and the second substrate 20 are transparent substrates, and a top view of the laminated body when viewed from the opposite surface 10X side of the first substrate 10 is shown on the left side, and a bottom view of the laminated body when viewed from the opposite surface 20X side of the second substrate 20 is shown on the right side. In the top view in FIG. 8(C), a state in which virtual images 30 of the alignment mark portions 22 of the second substrate 20 appear in the respective lens portions 11 of the first substrate 10 is indicated by solid circles. Regarding the alignment, a similar description to that of Embodiment 1 above applies.

Moreover, since the first substrate 10 has the cut-away portions 83, as shown in the top view on the left side in FIG. 8(C), in the laminated state, the other ends (on the opposite side to the circular ends) of the conductive films 84a and 84b of the second substrate 20 are exposed, so that external leads can be connected to the other ends of the conductive films 84a and 84b.

### Embodiment 4

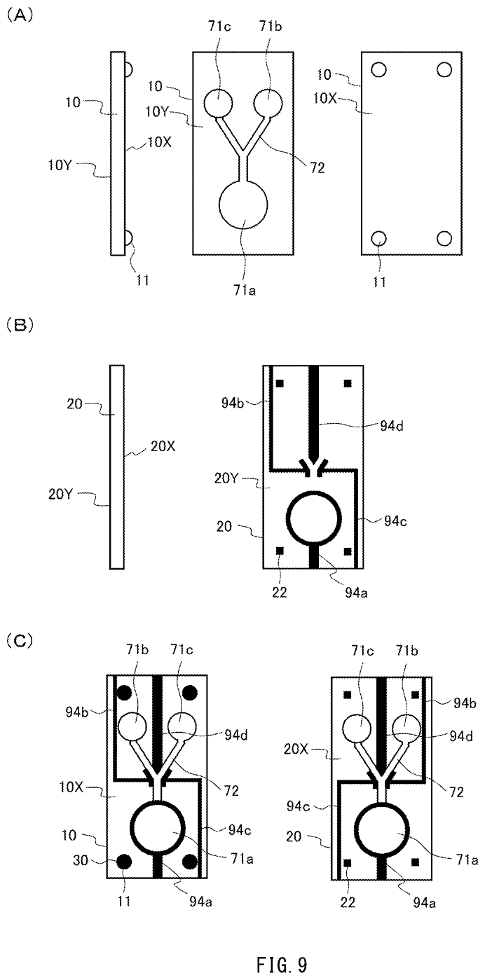

The present embodiment is a form in which the first substrate has a lens portion and a flow channel, and the second substrate has an alignment mark portion and a conductive film, and will be described using FIG. 9.

FIG. 9(A) schematically shows the first substrate 10, which is the same as the first substrate 10 in FIG. 7(A). In FIG. 9(A), a plan view of the upper surface, that is, the opposite surface 10X is shown on the right side, a plan view of the lower surface, that is, the facing surface 10Y is shown in the middle, and a side view is shown on the left side.

FIG. 9(B) schematically shows the second substrate 20, and a plan view of an upper surface, that is, the facing surface 20Y thereof is shown on the right side, and a side view thereof is shown on the left side. The second substrate 20 has alignment mark portions 22 similar to those of Embodiment 1. The second substrate 20 further has a plurality of conductive films 94a, 94b, 94c, and 94d extending inward from the two ends of the second substrate 20 on its short sides. In the state of the laminated body, the conductive film 94a is located on the outer periphery of the region surrounded by the recess 71a, and the conductive films 94b, 94c, and 94d are arranged around the branch point of the branching flow channel formed by the recess 72 and at positions where the conductive films are not in contact with the inside of the flow channel.

It is preferable that the alignment mark portions 22 and the circular conductive films 94a, 94b, 94c, and 94d of the second substrate 20 are formed in the same step, as in the case of Embodiment 1.

FIG. 9(C) schematically shows the laminated body in which the first substrate 10 and the second substrate 20 are laminated together. FIG. 9(C) shows an example in which the first substrate 10 and the second substrate 20 are transparent substrates, and a top view of the laminated body when viewed from the opposite surface 10X side of the first substrate 10 is shown on the left side, and a bottom view of the laminated body when viewed from the opposite surface 20X side of the second substrate 20 is shown on the right side. In the top view in FIG. 9(C), a state in which virtual images 30 of the alignment mark portions 22 of the second substrate 20 appear in the respective lens portions 11 of the first substrate 10 is indicated by solid circles. Regarding the alignment, a similar description to that of Embodiment 1 above applies.

### Embodiment 5

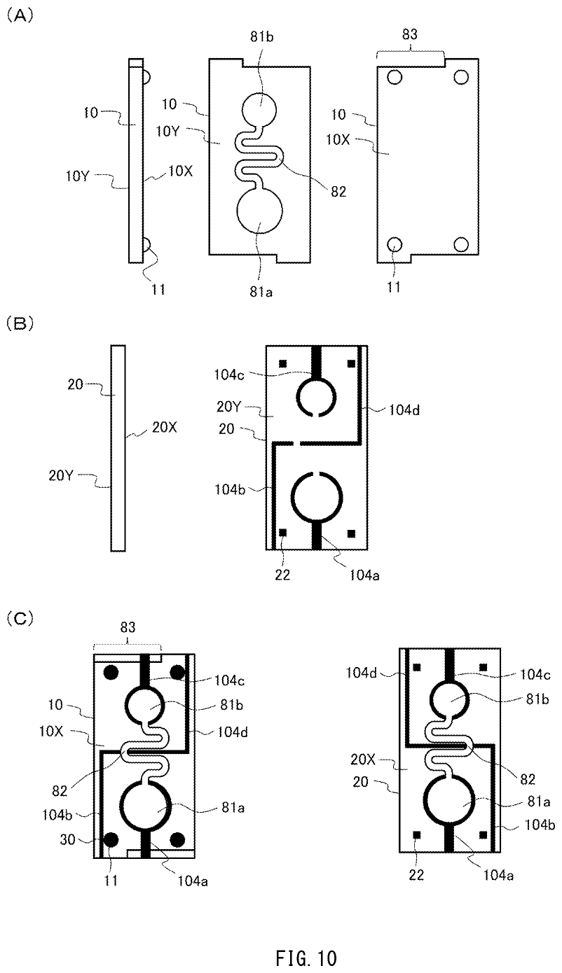

The present embodiment is a form in which the first substrate has a lens portion and a cut-away portion, and the second substrate has an alignment mark portion and a conductive film, and will be described using FIG. 10.

FIG. 10(A) schematically shows the first substrate 10, which is the same as the first substrate 10 in FIG. 8(A). In FIG. 10(A), a plan view of the upper surface, that is, the opposite surface 10X is shown on the right side, a plan view of the lower surface, that is, the facing surface 10Y is shown in the middle, and a side view is shown on the left side.

FIG. 10(B) schematically shows the second substrate 20, and a plan view of an upper surface, that is, the facing surface 20Y thereof is shown on the right side, and a side view thereof is shown on the left side. The second substrate 20 has alignment mark portions 22 similar to those of Embodiment 1. The second substrate 20 further has a plurality of conductive films 104a, 104b, 104c, and 104d. In the state of the laminated body, the conductive films 104a and 104c are located on the outer peripheries of the respective regions surrounded by the recesses 81a and 81b, and the conductive films 104b and 104d are arranged at positions where the conductive films are not in contact with the inside of the flow channel formed by the recess 82.

It is preferable that the alignment mark portions 22 and the conductive films 104a, 104b, 104c, and 104d of the second substrate 20 are formed in the same step, as in the case of Embodiment 1.

FIG. 10(C) schematically shows the laminated body in which the first substrate 10 and the second substrate 20 are laminated together. FIG. 10(C) shows an example in which the first substrate 10 and the second substrate 20 are transparent substrates, and a top view of the laminated body when viewed from the opposite surface 10X side of the first substrate 10 is shown on the left side, and a bottom view of the laminated body when viewed from the opposite surface 20X side of the second substrate 20 is shown on the right side. In the top view in FIG. 10(C), a state in which virtual images 30 of the alignment mark portions 22 of the second substrate 20 appear in the respective lens portions 11 of the first substrate 10 is indicated by solid circles. Regarding the alignment, a similar description to that of Embodiment 1 above applies.

Moreover, since the first substrate 10 has the cut-away portions 83, as shown in the top view on the left side in FIG. 10(C), in the laminated state, portions of the conductive films 104a and 104c of the second substrate 20 are exposed, so that external leads can be connected to the exposed portions of the conductive films 104a and 104c.

### Embodiment 6

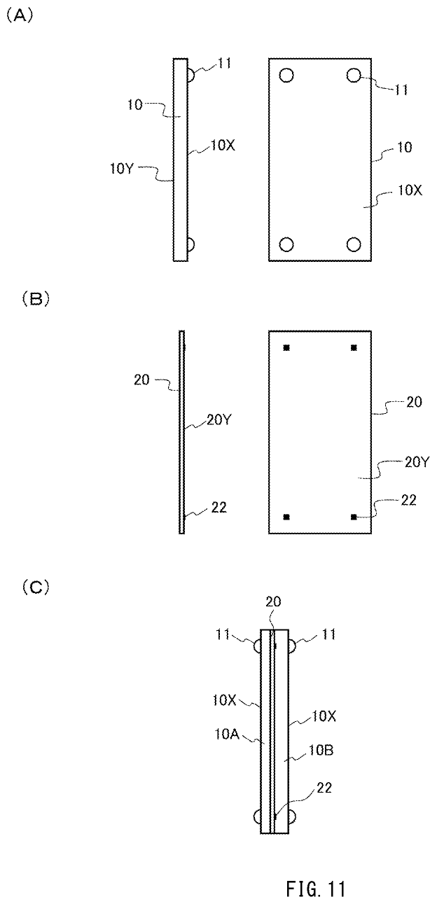

The present embodiment is a form in which the laminated body assembly kit further includes a third substrate having a lens portion, and will be described using FIG. 11.

FIG. 11(A) schematically shows a substrate 10 having lens portions 11, and a plan view of an upper surface, that is, the opposite surface 10X thereof is shown on the right side, and a side view thereof is shown on the left side. The substrate 10 has the same structure as the first substrate 10 shown in FIG. 3(A) described above. In the present embodiment, two substrates 10 having lens portions 11 are used as a first substrate and a third substrate that have lens portions 11. In the following description, the first substrate is denoted by 10A, and the third substrate is denoted by 10B, for the sake of convenience.

FIG. 11(B) schematically shows a second substrate 20, and a plan view of an upper surface, that is, the facing surface 20Y thereof is shown on the right side, and a side view thereof is shown on the left side. The second substrate 20 is the second substrate 20 shown in FIG. 3(A) described above and has the alignment mark portions 22.

FIG. 11(C) schematically shows a laminated body in which the two substrates 10 (first substrate 10A and third substrate 10B) and the second substrate 20 are laminated together, and is a side view of the laminated body.

In the present embodiment, each of the first substrate 10A and the third substrate 10B has the lens portions 11 at positions corresponding to the alignment mark portions 22 of the second substrate 20. The first substrate 10A is arranged such that the facing surface 10Y thereof faces one of the surfaces of the second substrate 20, with use of the alignment mark portions 22, and the third substrate 10B is arranged such that the facing surface 10Y thereof faces the other surface of the second substrate 20, with use of the alignment mark portions 22. At this time, the lens portions 11 of the first substrate 10A and the lens portions 11 of the third substrate 10B are aligned with the alignment mark portions 22 of the second substrate 20.

In the present embodiment, the alignment marks 22 of the second substrate 20 may be formed on either one of the surfaces thereof or on both surfaces, for example.

In the former case, a form is conceivable, for example, in which the alignment mark portions 22 are formed on the facing surface 20Y of the second substrate 20 that faces the first substrate 10A. Even when the alignment mark portions 22 are formed on the facing surface 20Y that faces the first substrate 10A, the alignment mark portions 22 also need to function as the alignment mark portions 22 for the third substrate 10B on the surface side that faces the third substrate 10B. In this case, when a transparent substrate, for example, is used as the second substrate 20, the alignment mark portions 22 on the first substrate 10A side can be checked from the third substrate 10B side as well, and thus, alignment can be performed. Note that the same applies to the case where the second substrate 20 has the alignment mark portions 22 on the surface that faces the third substrate 10B.

In the latter case, for example, a form in which separate alignment marks 22 are formed on the two surfaces of the second substrate 20, and a form in which the second substrate 20 has through holes, columnar bodies are disposed in the through holes, and exposed surfaces of the columnar bodies at the two ends thereof serve as the alignment mark portions 22 are conceivable. It is preferable that the alignment mark portions 22 are formed on the two surfaces of the second substrate 20, because, for example, setting is easier when positioning the alignment marks 22 of the second substrate 20 at the focal positions of the lens portions 11 for each of the first substrate 10A and the third substrate 10B.

According to the present embodiment, even when three substrates are used as described above, alignment can be performed with excellent accuracy. Therefore, providing functional portions such as the conductive films on the facing surfaces of the three substrates makes it possible to, for example, design more complex functional portions for a laminated body in which the substrates are laminated together.

### Embodiment 7

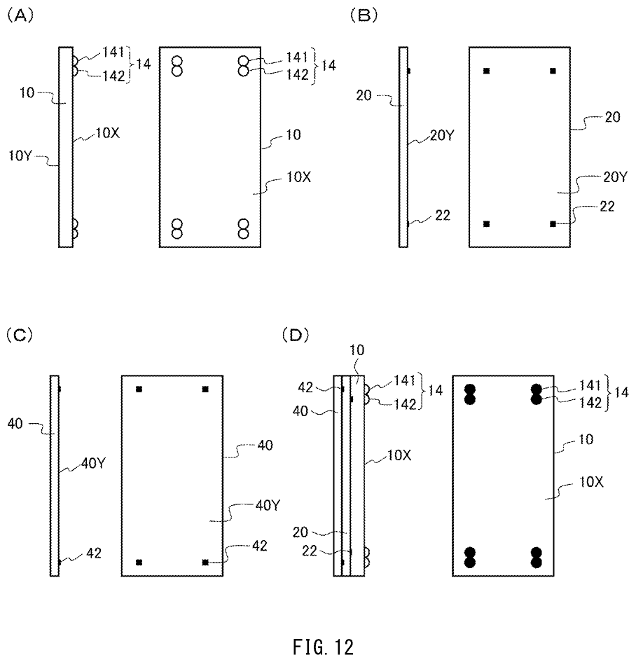

The present embodiment is a form in which the laminated body assembly kit further includes a third substrate having an alignment mark portion, and will be described using FIG. 12.

FIG. 12(A) schematically shows a first substrate 10 having lens portions 14, and a plan view of an upper surface, that is, the opposite surface 10X thereof is shown on the right side, and a side view thereof is shown on the left side. The first substrate 10 has the lens portions 14 respectively in the four corners of the opposite surface 10X, and the lens portions 14 each have two lenses 141 and 142 that are consecutively arranged in a longitudinal direction.

FIG. 12(B) schematically shows a second substrate 20, and a plan view of an upper surface, that is, the facing surface 20Y thereof is shown on the right side, and a side view thereof is shown on the left side. The second substrate 20 is the second substrate 20 shown in FIG. 3(A) described above and has the alignment mark portions 22. Note that the side view in FIG. 12(B) shows the alignment mark portions 22 of the second substrate 20 as alignment mark portions 22 having a certain thickness in order to indicate the positions thereof, however, this thickness does not hinder the lamination to the first substrate 10 during the lamination process, which will be described later.

FIG. 12(C) schematically shows a third substrate 40, and a plan view of an upper surface, that is, a facing surface 40Y thereof is shown on the right side, and a side view thereof is shown on the left side. The third substrate 40 is similar to the second substrate 20 except that alignment mark portions 42 are positioned in portions where the alignment mark portions 42 do not overlap the alignment mark portions 22 of the second substrate 20 when the third substrate 40 is laminated to the second substrate 20. Note that the side view in FIG. 12(C) shows the alignment mark portions 42 of the third substrate 40 as alignment mark portions 42 having a certain thickness in order to indicate the positions thereof, however, this thickness does not hinder the lamination to the second substrate 20 during the lamination process, which will be described later.

FIG. 12(D) schematically shows a laminated body in which the first substrate 10, the second substrate 20, and the third substrate 40 are laminated together, and a plan view of a lower surface, that is, the opposite surface 10X of the first substrate 10 in the laminated body is shown on the right side, and a side view of the laminated body is shown on the left side. In the plan view in FIG. 12(D), a state in which virtual images of the alignment mark portions 42 of the third substrate 40 and the alignment mark portions 22 of the second substrate 20 appear in the lenses 141 and 142 of the lens portions 14 of the first substrate 10 is indicated by solid circles. Note that the side view in FIG. 12(D) shows the alignment mark portions 22 of the second substrate 20 and the alignment mark portions 42 of the third substrate 40 as having certain thicknesses as in FIGS. 12(B) and 12(C); however, these thicknesses are illustrated in order to clearly show the positional relationship and should not be interpreted as showing embedding in the first substrate 10 or the second substrate 20.

In the present embodiment, the second substrate 20 and the third substrate 40 have the respective alignment mark portions 22 and 42 such that the alignment mark portions are located at different positions when the two substrates are laminated together. On the other hand, the first substrate 10 has the lens portions 14 each including the two lenses 141 and 142 such that the lenses correspond to the respective alignment mark portions 22 and 42 when the second substrate 20 and the third substrate 40 are laminated to the first substrate 10. Then, first, the first substrate 10 is arranged on the second substrate 20 such that the facing surface 10Y thereof faces the second substrate 20, with use of the alignment mark portions 22 of the second substrate 20 and the lenses 142 of the lens portions 14 of the first substrate 10. Next, the first substrate 10 is arranged on the third substrate 40 via the second substrate 20 with use of the alignment mark portions 42 of the third substrate 40 and the lenses 141 of the lens portions 14 of the first substrate 10.

According to the present embodiment, even when three substrates are used as described above, alignment can be performed with excellent accuracy. Therefore, providing functional portions such as the conductive films on the facing surfaces of the three substrates makes it possible to, for example, design more complex functional portions for a laminated body in which the substrates are laminated together.

As shown in the foregoing embodiments, according to the present invention, for example, even when complex pattern portions, such as the above-described conductive films, recesses, and the like, are formed on the facing surface of the first substrate and the facing surface of the second substrate, for example, the first substrate and the second substrate can be easily aligned simply by checking the image of the alignment mark portion of the second substrate in the lens portion of the first substrate. As described in the foregoing embodiments, for example, in the case where pattern portions such as a conductive film, a recess, and the like are arranged with high density on at least one of the first substrate and the second substrate, the present invention is especially useful because alignment can be easily performed. Moreover, since the alignment mark portion of the second substrate is detected as an image that is formed in the lens portion of the first substrate, the alignment mark portion may be an extremely small mark, for example. Therefore, in the case where the alignment mark portion is arranged on the facing surface of the second substrate as described above, for example, even when pattern portions are arranged with high density, the alignment mark portion can be easily arranged in a portion where no pattern portions are present. Moreover, in the case where the alignment mark portion is arranged on the opposite surface of the second substrate, for example, the entire facing surface can be used to form pattern portions thereon, and on the other hand, the alignment mark portion can be arranged in any portion on the opposite surface.

Moreover, according to the present invention, the accuracy of the positional relationship of the various portions can be increased even more by, for example, forming the lens portion and the recess of the first substrate through the same processing, and forming the alignment mark portion and the conductive film of the second substrate in the same step. Thus, an additional step can be omitted, and consequently, the process can be simplified.

In the present invention, furthermore, the alignment mark can also be arranged on the surface of the second substrate that is opposite to the facing surface. In this case, the entire facing surface of the second substrate can also be used as a functional portion.

Although the invention of the present application has been described with reference to the embodiments above, the invention of the present application is not limited to the foregoing embodiments. Various modifications that will be understood by a person skilled in the art can be made to the configurations and the details of the invention of the present application without departing from the scope of the invention.

This application is based upon and claims the benefit of priority from Japanese Patent Application No. 2017-242542 filed on Dec. 19, 2017, the entire disclosure of which is hereby incorporated by reference.

### INDUSTRIAL APPLICABILITY

As described above, with the laminated body alignment kit of the present invention, two substrates can be correctly aligned even when, for example, facing surfaces thereof have high-density pattern portions, and thus, a laminated body in which the two substrates are correctly aligned can be obtained.

### REFERENCE SIGNS LIST

10, 10A First substrate
10B, 40 Third substrate
11, 13, 14 Lens portion
141, 142 Lens
20 Second substrate
21, 22, 23, 24, 42 Alignment mark portion
241 Mark
61, 62, 71, 72, 81, 82 Recess
63 Through hole
64, 74, 84, 94, 104 Conductive film
83 Cut-away portion

1. A laminated body assembly kit with an alignment function, the kit comprising a first substrate and a second substrate that are to be laminated together,
wherein the first substrate has a lens portion on a surface thereof opposite to a facing surface thereof that faces the second substrate,
the second substrate has an alignment mark portion on at least one surface thereof,
the first substrate and the second substrate are respectively provided with the lens portion and the alignment mark portion such that, in a set laminated state, the alignment mark portion of the second substrate is located at a focal position of the lens portion of the first substrate, and
an image of the alignment mark portion that is formed in the lens portion in the set laminated state is an image indicating that the set laminated state has been achieved.

2. The laminated body assembly kit according to claim 1, wherein the first substrate and the second substrate are transparent substrates.

3. The laminated body assembly kit according to claim 1, wherein the first substrate has two or more of the lens portions, and the second substrate has two or more of the alignment mark portions.

4. The laminated body assembly kit according to claim 1, wherein, on a facing surface of the second substrate, a total area of the alignment mark portion is 3% or less of an area of the entire second substrate.

5. The laminated body assembly kit according to claim 1, wherein the lens portion has a spherical or aspherical surface.

6. The laminated body assembly kit according to claim 1, wherein the lens portion is a cylindrical lens.

7. The laminated body assembly kit according to claim 1, wherein the alignment mark portion has a quadrangular shape in a plan view.

8. A laminated body comprising a first substrate and a second substrate,
wherein the first substrate has a lens portion on a surface thereof opposite to a facing surface thereof that faces the second substrate,
the second substrate has an alignment mark portion on at least one surface thereof,
the first substrate and the second substrate are laminated together such that the lens portion of the first substrate and the alignment mark portion of the second substrate are located opposing each other, and
an image of the alignment mark portion of the second substrate that is formed in the lens portion is an image that is formed when the alignment mark portion is located at a focal position of the lens portion.

9. The laminated body according to claim 8, wherein the first substrate and the second substrate are transparent substrates.

10. The laminated body according to claim 8, wherein the first substrate has two or more of the lens portions, and the second substrate has two or more of the alignment mark portions.

11. The laminated body according to claim 8 wherein, on a facing surface of the second substrate, a total area of the alignment mark portion is 3% or less of an area of the entire second substrate.

12. The laminated body according to claim 8, wherein the lens portion has a spherical or aspherical surface.

13. The laminated body according to claim 8, wherein the lens portion is a cylindrical lens.

14. The laminated body according to claim 8, wherein the alignment mark portion has a quadrangular shape in a plan view.

15. A method for manufacturing a laminated body using the laminated body assembly kit with an alignment function according to claim 1, the method comprising:
placing the first substrate and the second substrate facing each other such that the lens portion and the alignment mark portion are located opposing each other,
aligning the first substrate and the second substrate with each other by adjusting an image of the alignment mark portion of the second substrate that is formed in the lens portion to an image that is formed when the alignment mark portion is located at a focal position of the lens portion, and
fixing the first substrate and the second substrate in this state.

16. The manufacturing method according to claim 15,
wherein the alignment mark portion has a quadrangular shape in a plan view,
the first substrate and the second substrate are aligned by being moved in directions of two axes that are orthogonal to each other, and
the two axes are parallel to respective pairs of opposing sides of the quadrangular shape.
